(19) United States
(12) Patent Application Publication
(10) Pub. No.: US 2018/0218890 A1
(43) Pub. Date: Aug. 2, 2018

(54) SPUTTERING COIL PRODUCT AND METHOD OF MAKING

(71) Applicant: HONEYWELL INTERNATIONAL INC., Morris Plains, NJ (US)

(72) Inventors: John A. DUNLOP, Mead, WA (US); Kevin T. HUBERT, Spokane Valley, WA (US); Jacob C. RUZICKA, Spokane, WA (US); Andrew N.A. WRAGG, Cheshire (GB); Michael D. BLONDELL, Liberty Lake, WA (US); William P. JARDEE, Mead, WA (US); Phillip F. JOHN, Medical Lake, WA (US); Edward P. LARA, Coeur d'Alene, ID (US); Wayne D. MEYER, Cheney, WA (US); Adam P. DAUB, Valleyford, WA (US); Scott A. BUCKHART, Greenacres, WA (US); Travis C. JUNTTILA, Post Falls, ID (US)

(21) Appl. No.: 15/746,647

(22) PCT Filed: Jul. 18, 2016
(86) PCT No.: PCT/US2016/042740

§ 371 Date: Jan. 22, 2018

Related U.S. Application Data
(60) Provisional application No. 62/196,210, filed on Jul. 23, 2015.

(51) Int. Cl. H01J 37/34; H01F 7/06; H01F 27/28; C23C 14/35

(52) U.S. Cl. CPC H01J 37/3458; C23C 14/35; H01F 27/28; H01F 7/06

(57) ABSTRACT

A high surface area coil for use with a physical vapor deposition apparatus comprising a first surface. At least a portion of the first surface has a macrotexture with a surface roughness between about 15 μm and about 150 μm. At least a portion of the first surface has a microtexture with a surface roughness between about 2 μm and 15 μm.

### TECHNICAL FIELD

The present disclosure relates to coils and coil sets used in physical vapor deposition apparatuses. More particularly, the present disclosure relates to coils that improve semiconductor product yield and methods of making these coils.

### BACKGROUND

Deposition methods are used in forming films of material across substrate surfaces. Deposition methods can be used, for example, in semiconductor device fabrication processes to form layers ultimately used in making integrated circuits and devices. An example of a known deposition method is physical vapor deposition (PVD). PVD methodologies may include sputtering processes. Sputtering includes forming a target of a material which is to be deposited, and providing the target as a negatively charged cathode proximate to a strong electric field. The electric field is used to ionize a low pressure inert gas and form a plasma. Positively charged ions in the plasma are accelerated by the electric field toward the negatively charged sputtering target. The ions impact the sputtering target, and thereby eject target material. The ejected target material is primarily in the form of atoms or groups of atoms, and can be used to deposit thin, uniform films on substrates placed in the vicinity of the target during the sputtering process.

Sputtering processes typically take place within a sputtering chamber. Sputtering chamber system components may include targets, target flanges, target sidewalls, shields, cover rings, coils, cups, pins and/or clamps, and other mechanical components. Often a coil is present in these systems and/or deposition apparatuses as an inductive coupling device to create a secondary plasma of sufficient density to ionize at least some of the metal atoms that are sputtered from the target. In an ionized metal plasma system, the primary plasma forms and is generally confined near the target by a magnetron, and subsequently gives rise to atoms being ejected from the target surface. The secondary plasma formed by the coil system produces ions of the material being sputtered. These ions are then attracted to the substrate by the field in the sheath that forms at the substrate surface. As used herein, the term “sheath” means a boundary layer that forms between a plasma and any solid surface. This field can be controlled by applying a bias voltage to the substrate. This is achieved by placing the coil between the target and the wafer substrate and increasing the plasma density and providing directionality of the ions being deposited on the wafer substrate. Some sputtering apparatuses incorporate powered coils for improved deposition profiles including via step coverage, step bottom coverage, and bevel coverage.

Surfaces within the sputtering chamber that are exposed to plasma may incidentally become coated with sputtered material deposited on these surfaces. Material that is deposited outside the intended substrate may be referred to as back-sputter or re-deposition. Films of sputtered material formed on unintended surfaces are exposed to temperature fluctuations and other stressors within the sputtering environment. When the accumulated stress in these films exceeds the adhesion strength of the film to the surface, delamination and detachment may occur, resulting in particulate generation. Similarly, if a sputtering plasma is disrupted by an electrical arc event, particulate may be formed both within the plasma, and from the surface that receives the arc force. Coil surfaces, especially those that are very flat or have sharply angular surfaces, may exhibit low adhesion strength resulting in undesirable particulate build up. It is known that particle generation during PVD is a potential cause of device failure and is one of the most detrimental factors that reduce functionality in microelectronic device fabrication.

Deposition of sputtering material can occur on the surfaces of sputtering coils. Coil sets generate particulate matter due to shedding from coil surfaces, especially those that are very flat or have sharply angular surfaces. During a sputtering process, often the particulates from within a sputtering chamber will be shed from the coils. To overcome this, sputtering chamber components can often be modified in a number of ways to improve their ability to function as particle traps and also reduce problems associated with particle formation.

It is desirable to develop suitably performing coils for use with a deposition apparatus, a sputtering chamber system and/or ionized plasma deposition system without causing shorts, plasma arcing, interruptions to the deposition process, or particle generation. Knurling coil surfaces is one method known to improve performance. However, further improvements are desired.

### SUMMARY

Disclosed herein is a high surface area coil for use with a physical vapor deposition apparatus comprising a first surface. At least a portion of the first surface has a macrotexture with a surface roughness between about 15 μm and about 150 μm. At least a portion of the first surface has a microtexture with a surface roughness between about 2 μm and 15 μm.

Also disclosed herein is a sputtering coil for use with a physical vapor deposition apparatus comprising a first surface. At least a portion of the first surface has a percent surface area between about 120 percent and about 300 percent.

Also disclosed herein is a method of forming a high surface area coil for use with a physical vapor deposition apparatus comprising forming a macrotexture on at least a portion of a first surface of a coil. The method also includes forming a microtexture on at least a portion of the first surface containing the macrotexture. After forming the macrotexture and forming the microtexture, the coil has a percent surface area of at least 120 percent.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1A is a top view of an exemplary coil that may be used with some sputtering systems.

FIG. 1B is a side view of an exemplary coil that may be used with some sputtering systems.

FIG. 2 illustrates an example knurling pattern that may be used on a material surface.

FIG. 3 illustrates an example knurling pattern that may be used on a material surface.

FIG. 4 illustrates an example knurling pattern that may be used on a material surface.

FIG. 5 is an image of a comparative example of a knurled surface.

FIG. 6 is an image of an example of a treated surface.

FIG. 7 illustrates an exemplary method of creating a treated surface.

FIG. 8 illustrates an exemplary method of creating a treated surface.

FIGS. 9A and 9B are images of an inventive example of a treated surface.

FIGS. 10A and 10B are images of an inventive example of a treated surface.

FIG. 11A is an image of a comparative example of a sputtering coil material surface after knurling.

FIG. 11B is an image of an inventive example of a sputtering coil material treated with the methods of the instant disclosure.

FIG. 11C is an image of an inventive example of a sputtering coil material treated with the methods of the instant disclosure.

FIG. 12A is an image of an exemplary knurled surface of a sputtering coil material at 10× magnification.

FIG. 12B is an image of an exemplary knurled surface of a sputtering coil material at 20× magnification.

FIG. 13A is an image of an exemplary sputtering coil material treated with the methods of the instant disclosure at 10× magnification.

FIG. 13B is an image of an exemplary sputtering coil material treated with the methods of the instant disclosure at 20× magnification.

FIG. 14A is an image of an exemplary sputtering coil material treated with the methods of the instant disclosure at 10× magnification.

FIG. 14B is an image of an exemplary sputtering coil material treated with the methods of the instant disclosure at 20× magnification.

### DETAILED DESCRIPTION

The present disclosure provides a coil with an increased surface area for use in physical vapor deposition apparatuses. The coil is comprised of a material having a surface with a macrotexture defining a first surface roughness and a microtexture defining a second surface roughness. The macrotexture may comprise any one of a wide range of patterned surfaces, for example, knurled, over knurled, machined, or embossed patterns. The microtexture may comprise any one of an etched or particle blasted pattern that adds further to the surface of the coil. The disclosed surface texturing can be applied to coils, targets, shielding and any areas within the sputtering chamber that are exposed to re-deposition from the sputtering plasma and could thus contribute to particulate generation.

To improve product yield, sputtering chamber components can be modified to function as sputtered material adhesion sites and particle traps. This is a feature of the current disclosure. In some embodiments, the current disclosure comprises a coil or coil set that has a specific surface that reduces particle flaking by increasing surface area and mechanical keying to the substrate while eliminating flat and angular surfaces.

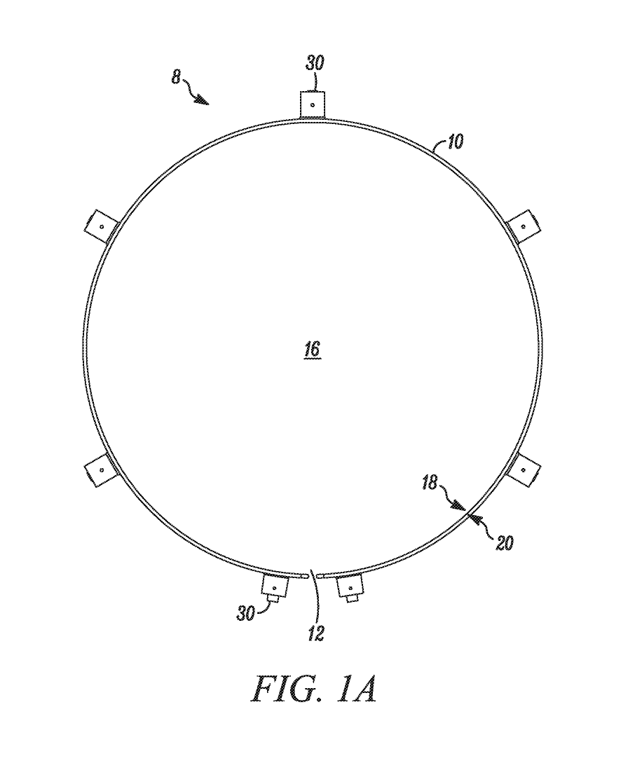

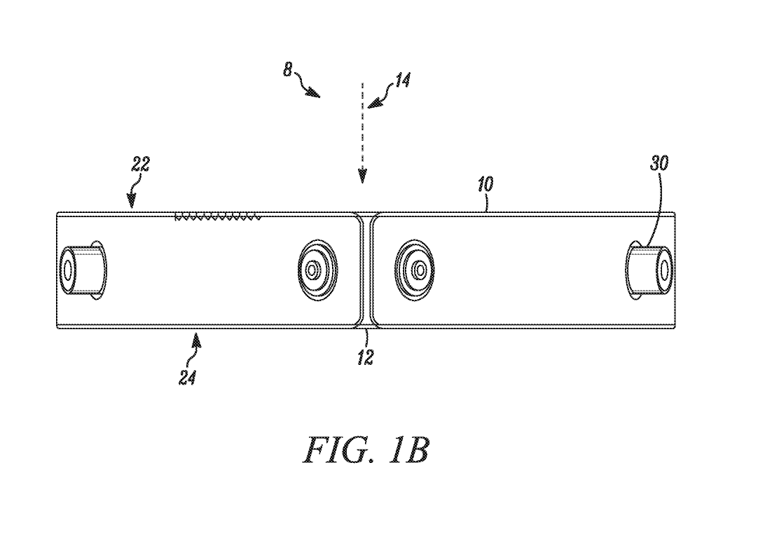

FIG. 1A illustrates a sputtering coil as viewed in the axial direction. FIG. 1B illustrates a sputtering coil viewed from the side or normal to the plane of FIG. 1A. As shown in FIGS. 1A and 1B, in some embodiments, a sputtering coil 8 may be formed as a substantially circular ring 10 of material. The coil 8 may be shaped to form a ring 10 in a complete circle around a center 16. The coil 8 may optionally be formed into a ring 10 with a gap 12 in the circumference. The coil 8 may be formed into a ring 10 having a central axis 14. The ring 10 defines an inner diameter. The coil 8 may have an inside surface 18 defined as the surface facing inward toward the center 16 of the ring 10. The coil 8 may have an outside surface 20 defined as the surface of the ring 10 pointed radially away from the center 16 of the ring 10.

The ring 10 may have a top surface 22 comprising the surface of the coil material that lies in a plane normal to the central axis 14 of the ring 10 and oriented to face in the direction of the sputtering target (not shown) during sputtering operations. The ring 10 may have a bottom surface 24 comprising the surface of the coil 8 that lies in a plane normal to the central axis 14 of the ring 8 and opposite the top surface 22. Typically the bottom surface 24 will be oriented to face in the direction of the substrate or away from the sputtering target (not shown).

The outside surface 20 of the ring 10 may contain a boss 30 or a plurality of bosses 30 extending from the outside surface 20 of the ring 10. The bosses 30 extend radially outward in a direction away from the center 16 or central 14 axis of the ring 10. The bosses 30 are tube shaped structures that may be used to hold the coil 8 in place in a sputtering apparatus. During use, the area of the boss 30 facing the sputtering target is exposed to deposition from the target. If the coil surface is relatively smooth, it may allow a film of back-sputtered material to deposit on the boss surface. This deposit expands and contracts during deposition with the heating and cooling steps that are part of the deposition process. Frequently, adhesion of this deposit fails, releasing particulate. Exposed boss areas in the invention may be subjected to the same macro and microtexturing as the ring surfaces for significantly improved adhesion and increased surface areas. This treatment reduces delamination of the boss surface, detachment of deposit, and particulate creation.

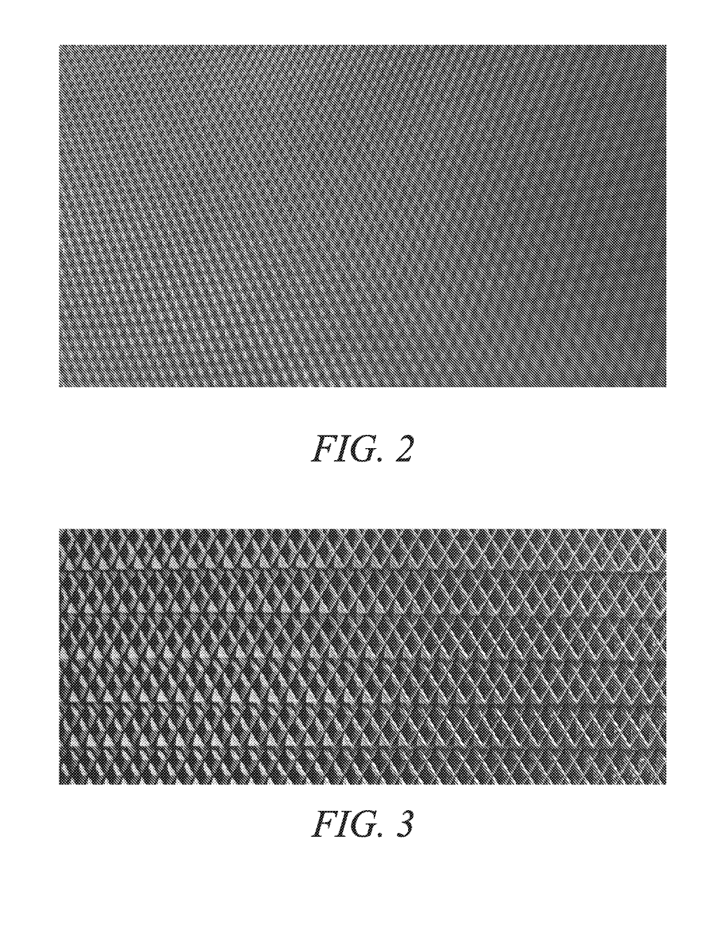

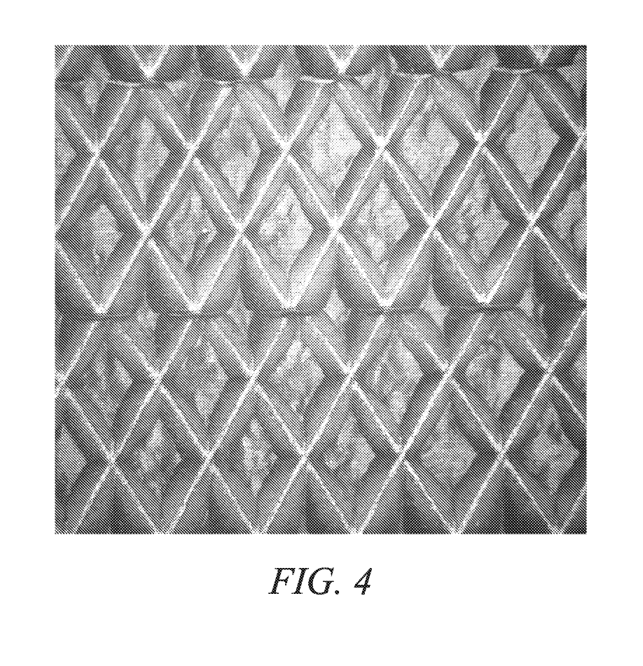

In some embodiments, at least a portion of a surface of the coil 8 may have a textured surface. FIGS. 2-4 illustrate some examples of surfaces that may form a macrotexture on a surface. FIG. 2 shows an example knurled macrotexture. FIG. 3 shows an example alternative knurled macrotexture. FIG. 4 shows an enlarged image of the alternative knurled macrotexture of FIG. 3.

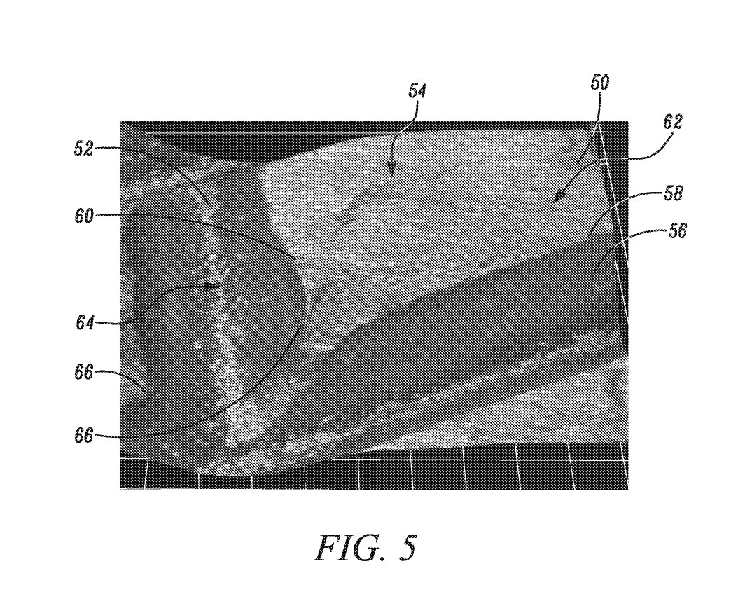

FIG. 5 is a comparative example. In some embodiments, the macrotexture of the instant disclosure may be formed as a knurled surface. As shown in FIG. 5, the relative planarity of the knurled plateaus and the valleys and facets formed by the knurling tool are apparent.

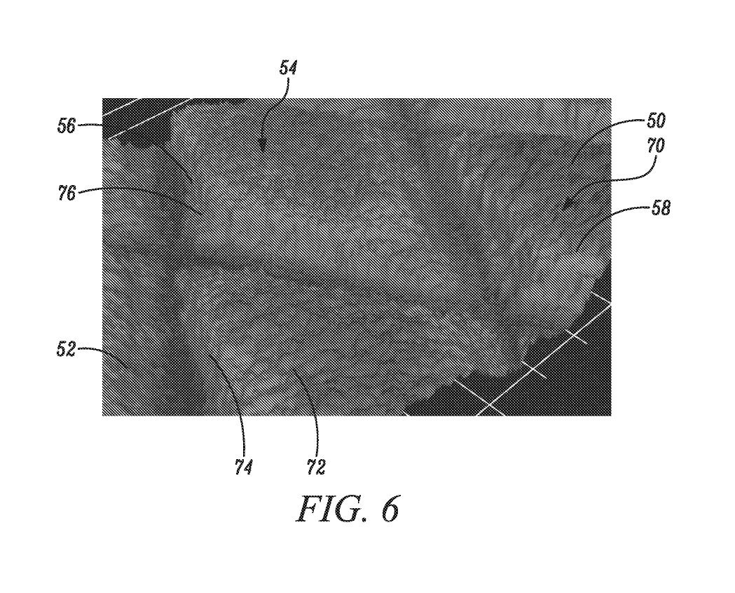

As an inventive example, FIG. 6 shows a coil having an additional microtexture 72. FIG. 5 will first be described followed by a description of FIG. 6. As shown in FIG. 5, as a comparative example, a coil surface has a knurled macrotexture pattern. The image in FIG. 5 illustrates certain features present when only knurling has been performed. For example, the knurled pattern contains plateaus 50 such as raised flat portions separated by grooves 52 or indentations also referred to as valleys. The valleys 52 separate and define the plateaus 50 and may be any repetitive pattern such as repeating intersecting lines, repeating V-shaped lines, or crisscrossed lines, as some examples. The plateaus 50 may be defined by any repetitive pattern defined by the valleys 52 such as diamonds, interlaced knurls, squares, or zig-zags, or potentially nearly smooth surfaces.

The coil of FIG. 5 has a knurled macrotexture that contains certain features such as a substantially horizontal surface 54 or face of the plateaus 50 surrounded by relatively vertical planar side walls 56. The plateaus 50 and side walls 56 meet at an interface 58 defining a border between them. In some embodiments, this border can form a ridgeline that may comprise a sharply defined edge 60. Formations that contain these sharply defined edges 60 can be referred to as macrotextures that contain formations of high angularity. Notable features that are formed by the knurled pattern are the relatively smooth planar surfaces 62 in areas of the faces 54 of the plateaus 50 and the relatively smoothly rounded bottoms 64 of the valleys 52. The plateaus 50 may also form pointed corners 66 where the face of the plateau 50 and two side walls 56 meet.

The macrotexture has an arithmetic mean surface roughness (Ra) as defined by various international standards that can be measured. One method of measurement may be made by use of a laser confocal microscope such as the Keyence Color 3D Laser Confocal Microscope model VK9710. In general, the surface roughness of the macrotexture is defined by an average of the absolute values of depth of each valley 52 and the absolute values of the height of the highest point on each plateau 50 when measured from a mean value between these values. For example, the height of the macrotexture can be about 300 μm Ra, where the term Ra refers to the roughness aspect. In some embodiments the surface roughness may have an Ra value as low as 15 μm, 25 μm, or 35 μm, or as high as 75 μm, 150 μm, or 400 μm, or may be within a range delimited by a pair of the foregoing values, such as 15 μm to 400 μm, 25 μm to 150 μm, or 35 μm to 75 μm, depending on the starting surface the invention is applied to.

The macrotexture also has a surface area that can be measured by use of a laser confocal microscope such as the Keyence Color 3D Laser Confocal Microscope model VK9710. In some embodiments, the surface area comprises the combined area of the plateaus 50, sidewalls 56, and valleys 52. This combined surface area is greater than the surface area prior to knurling or other surface patterning or texturization. This is discussed further below.

By contrast, in the inventive example, as shown in FIG. 6, the surface contains the same macrotexture as in FIG. 5, however the surfaces in FIG. 6 contain additional microtexture 72. In this image, certain elements that are present in FIG. 5 are lacking. For example, in FIG. 6 rather than a flat planar surface 62 on the plateaus 50 in FIG. 5, there is a rough undulating surface 70 containing a microtexture 72 with rises and indentations. The plateaus 50 in FIG. 6 lack the planar surface 62 produced with just a knurled pattern. Additionally, the interfaces 58 of the horizontal surface 54 and the vertical planar side walls 56 in FIG. 6 have a rough textured border 74 rather than a sharply defined edge 60 as in FIG. 5. This microtextured pattern results in a surface having fewer sharply angled interfaces and thus the surface can be referred to as having a reduced angularity. In FIG. 6, the locations 76 where the horizontal surface 54 and two side walls meet are roughened as well, rather than pointed. The valleys 52 of FIG. 6 substantially lack the smoothly rounded bottom surfaces 64. Instead, like the surface of the plateaus 50, the valleys 52 in FIG. 6 have a microtexture 72 comprising rises and indentations.

In some embodiments, the roughness or microtexture 72 is present over the entire macrotexture including the plateaus 50 and side walls 56. In some embodiments, the roughness or microtexture 72 extends through the valleys 52.

Like the macrotexture, the microtexture arithmetic mean surface roughness (Ra) can also be measured. For example, the Ra of the microtexture 72 can be measured with a laser confocal microscope such as the Keyence Color 3D Laser Confocal Microscope model VK9710. Just as the surface area increases when a macrotexture is added to it, the surface area increases further when a microtexture 72 is added to a surface that already has a macrotexture. For example, a height of the microtexture 72 can be 5 Ra, where the term Ra refers to the roughness aspect. In some embodiments the surface roughness may have an Ra value as low as 2 μm, 3 μm, or 5 μm, or as high as 10 μm, 15 μm, or 20 μm, or may be within a range delimited by a pair of the foregoing values, such as 2 μm to 20 μm, 3 μm to 15 μm, or 5 μm to 10 μm, depending on the beginning surface the invention is applied to.

With the addition of a microtexture 72, the surfaces of the coil have a significantly enhanced surface area. The value of the surface area change can be measured and given as a percent surface area. The percent surface area is defined as the actual surface area of a given surface divided by the planar surface area of the same surface. As used herein, the term actual surface area is the total area of interest of the exposed coil material; and the term planar surface area is the surface area of a hypothetical planar surface superimposed over the area occupied by the actual surface area. i.e. the surface area if texturing were not present. Example values of microtexture 72 surface areas are discussed further below.

Thus the actual surface area takes into account changes in surface area as a result of the surface's micro and macrotexture. For a perfectly smooth surface the percent surface area is 100%, because without a texture, the actual surface is equivalent to a hypothetical two dimensional planar surface. Once any changes are made in the surface texture or smoothness, the actual surface area increases. In other words, the actual surface of the object leaves a hypothetical two dimensional plane and enters into three dimensional space. Each surface that is no longer parallel to the hypothetical two dimensional plane increases in actual surface area due to geometry.

An actual surface area can be measured using a laser confocal microscope such as the Keyence Color 3D Laser Confocal Microscope model VK9710. This actual surface area can then be compared to the planar surface area of the measured area. The percent surface area increase can be calculated by dividing the actual surface area by an equivalent planar surface area.

In some embodiments, a percent surface area increase of a non-planar surface such as a cylinder that has been given a macro and microtexture can also be measured. For this measurement, the surface in question is mapped and the data is subsequently processed (i.e. flattened) to remove underlying geometry. This allows the original surface to be represented by a planar surface while the macro and microtexture remains intact. The actual surface area increase can then be measured by direct comparison to the original surface area of the underlying geometry much in the same way that a planar surface can be compared.

In some embodiments, the surface area can be enhanced or controlled by controlling the microtexture depth. The instant disclosure contemplates a variety of methods for applying a microtexture to a surface having a macrotexture. In some embodiments, the method first includes forming a macrotexture on a surface followed by, for example, etching or grit blasting the macrotextured surface to add the microtexture. In some embodiments, more than one treatment may be used to create the microtexture, for example, grit blasting in combination with etching. This microtexture surface treatment transforms the initial angular, faceted, low area surface into a rounded conchoidal surface with an enhanced surface area and high surface energy.

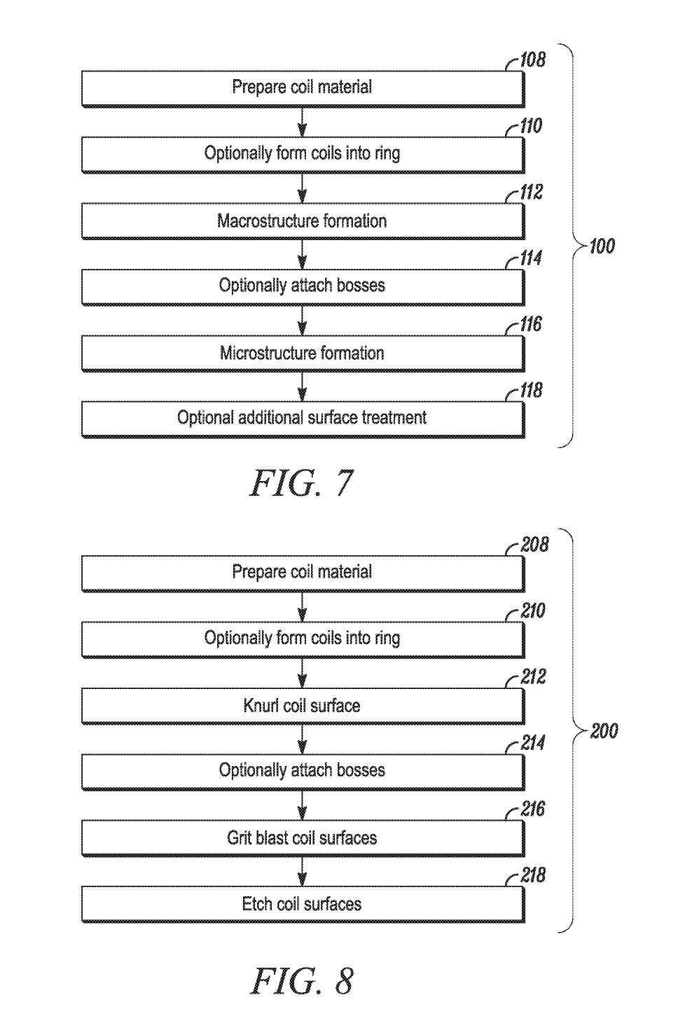

As shown in FIG. 7, in some embodiments, a method 100 of forming a sputtering coil with an enhanced surface area begins by preparing a sputtering coil material for surface treatment (step 108). Optional preparation steps may include taking a coil material and cutting it into the desired shape or size for forming a coil. The prepared coil material is then optionally formed into a circle or ring (step 110). In some embodiments the coil material is formed into a ring with a gap in the ring circumference. One method that may be used to form a coil material is rolling the coil material to form a ring then cutting the ring to form a gap in the ring circumference. In some embodiments, the coil may be formed into a ring after the coil surface treatment has been completed.

After the coil has been formed, in step 112, the macrotexture is formed on the surface of the ring. In some embodiments, the ring has a macrotexture formed only on certain surfaces. For example, the ring may have a macrotexture formed on one or more of the inner surface, outer surface, top surface, bottom surface, or bosses. In some embodiments, bosses can be attached to the coil after the microtexture has been formed on the surface. In step 114, bosses may optionally be attached to the coil before the microtexture has been formed on the surface. In step 116, a microtexture is formed on the surface of the coil. The treated coil having a macrotexture enhanced by a microtexture may then undergo an optional additional surface treatment in step 118. For example, the surface of the coil may be cleaned to remove chemicals or particles that remain on the coil after the microtexture formation step 116.

As illustrated in FIG. 8, an exemplary method 200 may be used to form the material of the current disclosure. In step 208, the coil material is prepared; for example the material may be punched or pressed from a master material to form a flat coil material that will later be shaped. The prepared coil material may optionally be formed into a ring in step 210. In general, the ring may be a complete circle. In some embodiments, a gap may be formed in the coil after the coil is formed into a ring. Alternatively, the ring may be initially formed in a substantially circular shape with a gap remaining in the circumference. In some embodiments, the coil material is formed into a ring before either the macrotexture formation step 212, or after the macrotexture formation but before the microtexture formation step 216. Alternatively, the coil may be formed into a ring after both the macrotexture formation step 212 and the microtexture formation step 216.

The coil material may undergo a macrotexture formation step 212 that includes knurling the surface of the coil material. The macrotexture formation step 212 may include adding any one of a knurled, over knurled, aggressive knurl, or super aggressive knurl pattern to the surface of the coil material. Suitable tools or subtractive methods may be used to form a specific pattern having regular depth patterns, including mechanical tools. A suitable tool comprises any mechanically patterning tool that achieves desired roughness contemplated and claimed.

The coil may optionally have bosses attached to the outer surface in step 214. In some embodiments, bosses may optionally be attached before forming a macrotexture on the coil surface or may be attached after forming a macrotexture. In some embodiments, bosses may optionally be attached after forming both the macrotexture and the microtexture. In some embodiments, bosses may undergo a similar surface treatment as the coil ring and have a macrotexture and microtexture formed on the surfaces.

A microtexture formation may include a grit blasting step 216. A grit blasting step 216 may be applied to a material having a macrotextured surface to form a microtexture. For example, a grit blasting step may include grit blasting using silicon carbide grit. In some embodiments, silicon carbide grit blasting provides certain advantages, such as the ability to detect residual grit on the surface of the coil. In some embodiments, a grit blasting step 216 may be used alone or in combination with another surface treatment step. For example, an etching step 218 using hydrofluoric acid may be used. Etching may be used to create the rough microtexture, removing sharp edges, and adding to the surface area. The surfaces of the coil can be treated with any of the above treatment steps. The top surface, the bottom surface, the inside surface, and the outside surface can all be subjected to these treatment steps. Additionally, the bosses can also be subjected to these surface texturing steps.

After completing the steps of the methods above, at least a portion of the coil surfaces have a macrotexture. In some embodiments the surface roughness may have an Ra value as low as 15 μm, 25 μm, or 35 μm, or as high as 75 μm, 150 μm, or 300 μm, or may be within a range delimited by a pair of the foregoing values, such as 15 μm to 300 μm, 25 μm to 150 μm, or 35 μm to 75 μm, depending on the beginning surface the invention is applied to.

After completing the steps of the methods above, at least a portion of the coil surfaces also have a microtexture. In some embodiments the surface roughness may have an Ra value as low as 2 μm, 3 μm, or 5 μm, or as high as 10 μm, 15 μm, or 20 μm, or may be within a range delimited by a pair of the foregoing values, such as 2 μm to 20 μm, 3 μm to 15 μm, or 5 μm to 10 μm, depending on the starting surface the invention is applied to.

Similarly, actual percent surface area increases can also be measured for both the macro and microtextures applied to coil surfaces. As used herein, the macrotexture percent surface area is the percent surface area of a given surface after a macrotexture has been added, in comparison to a planar surface. As used herein, the microtexture percent surface area is the percent surface area of a given surface after a microtexture has been added, in comparison to a planar surface. Using the methods of the instant disclosure, macrotexture surface area increases between 150 and 400 percent can be achieved versus a planar surface. Microtexture surface area increases between 140 and 300 percent can be achieved versus a planar surface. In some embodiments, the macrotexture surface area may have a percent value of at least 120 percent that of a planar surface. In some embodiments the macrotexture percent surface area may be as low as 120, 140, or 150 percent, or as high as 300, 400, or 1000 percent, or may be within a range delimited by a pair of the foregoing values, such as 120 to 1000 percent, 130 to 400 percent, or 150 to 300 percent. In some embodiments the microtexture percent surface area may have a percent value as low as 125, 140, or 160 percent, or as high as 300, 400, or 500 percent, or may be within a range delimited by a pair of the foregoing values, such as 125 to 500 percent, 140 to 400 percent, or 160 to 300 percent.

The methods of the present disclosure transform a traditionally knurled surface by increasing surface area, eliminating significant asperities, and increasing the surface energy. These transformations allow loose molecules of sputtered material to strongly adhere to invention surfaces. In addition, the disclosed process removes angular and flat areas from initial macrotextured surfaces resulting in reduced arcing during the sputtering process. A sputtering coil formed with the methods in the instant disclosure exhibit improved adhesion of re-deposited films, reducing particulate generation and improving product yield during use. The synergistic combination of better back-sputter adherence and minimized arcing enable higher product yield for semiconductor device fabricators.

### EXAMPLES

The following non-limiting Examples illustrate various features and characteristics of the present invention, which is not to be construed as limited thereto.

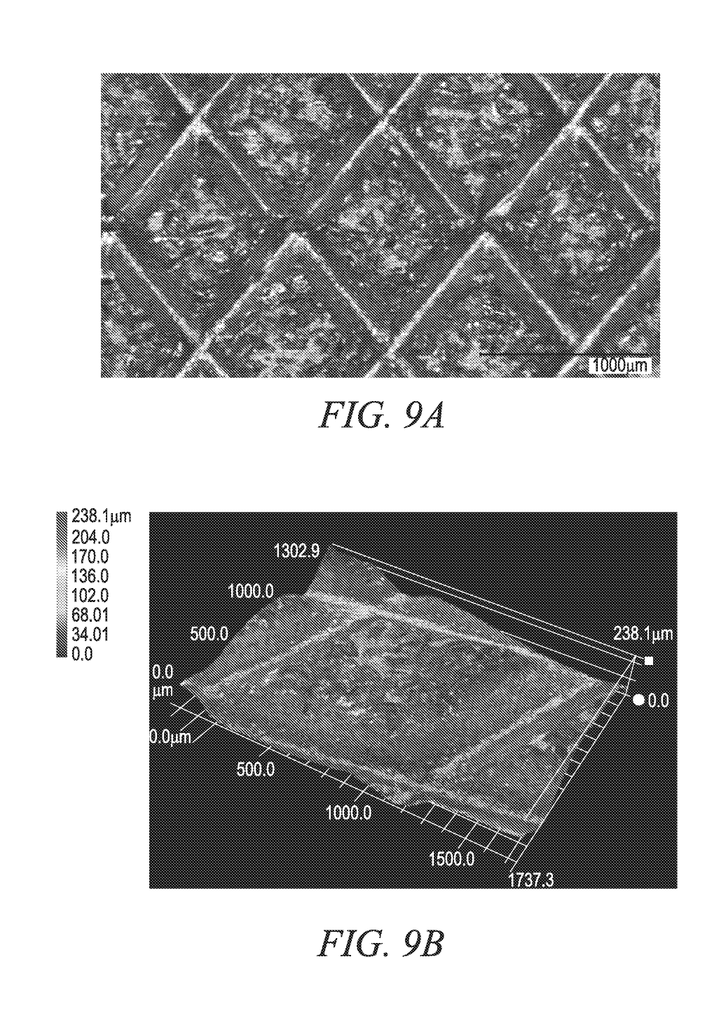

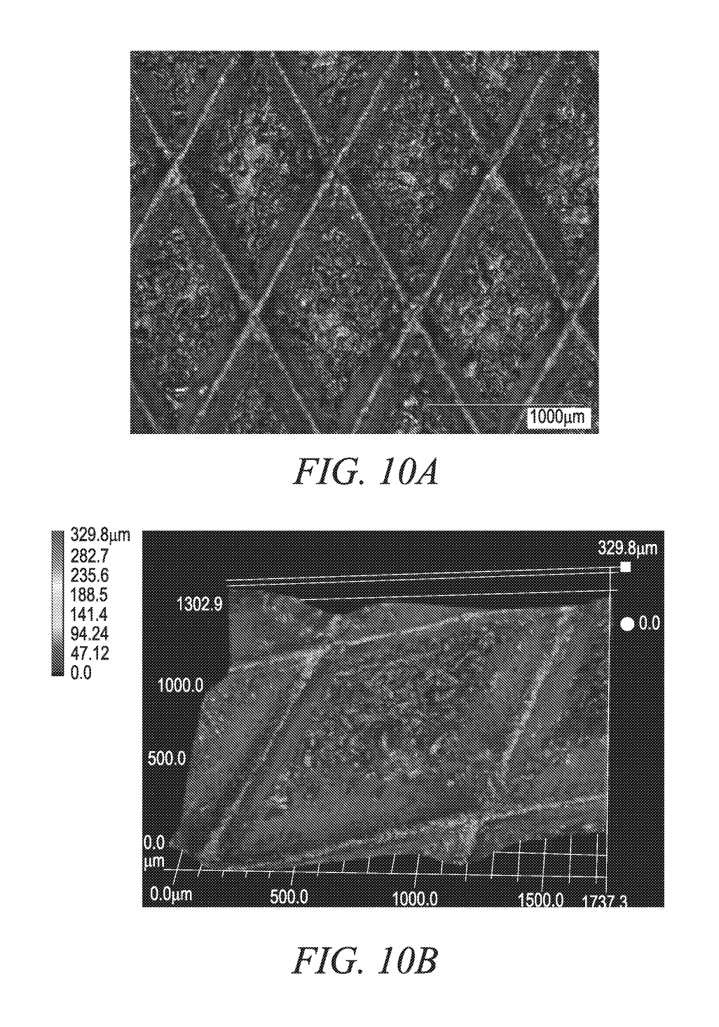

FIGS. 9A, 9B, 10A, and 10B were captured using a Keyence Digital Microscope model VHX-2000E at a magnification of 100×. FIGS. 9B and 10B were taken at the 100× magnification using the setting “Depth Up/3D” allowing the microscope to move focus from the lowest to highest points of the surface to construct a 3D image.

FIGS. 9A and 9B depict the macrotexture of the surface after undergoing a grit blast step. FIG. 9B shows the 3D image where some high spots may remain on the knurled surface.

FIGS. 10A and 10B are an inventive example of the knurled surface of FIGS. 9A and 9B after undergoing an etching step. The etch is able to further round parts of the knurled surface by removing and rounding any high or sharp edges. Additionally, the valleys have added roughness due to etching.

### Example 1: Visual Qualitative Assessment of Coil and Boss Features

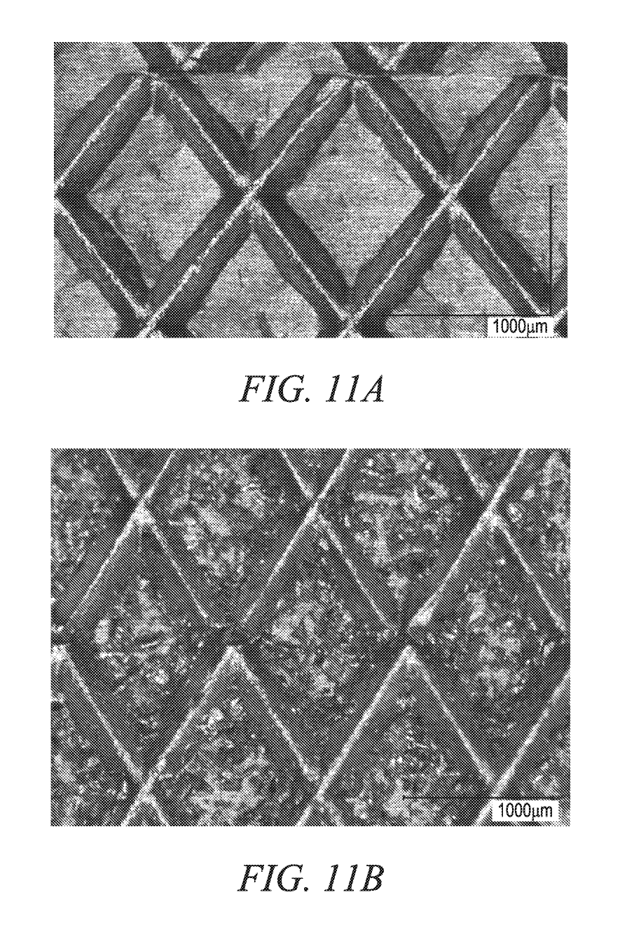

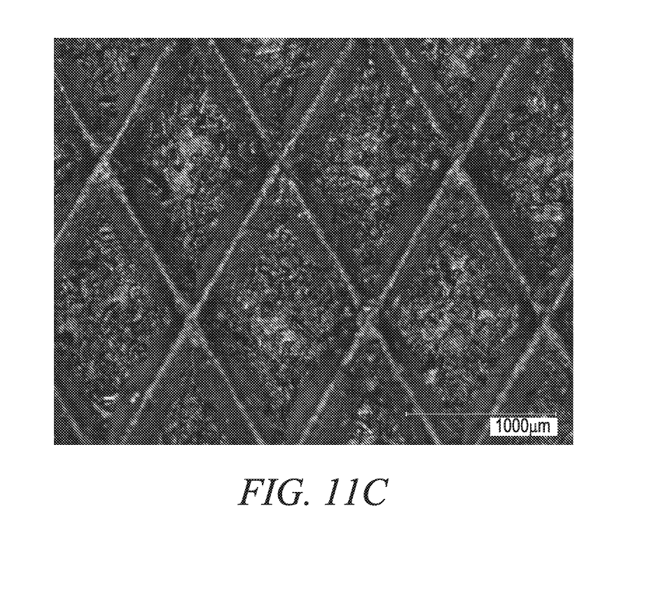

FIGS. 11A, 11B, and 11C were captured using a Keyence Digital Microscope model VHX-2000E at a magnification of 100×. The examples show a visual comparison of the three main surface treatments to create macro and microtexture.

Certain methodologies were employed to transform smooth coil surfaces into a texturized surface. Three major process steps were implemented to develop the surface texture: knurling, grit blasting and extended etching, evidenced in FIGS. 11A, 11B, and 11C, respectively. These images were taken using a Keyence Digital Microscope model VHX-2000E at a magnification of 100×. Beginning with coil surfaces, having a smooth surface, the first step, knurling, added the initial macrotexture that is shown in FIG. 11A. A summary of the visual observations are included in Table 1.

The knurling transformed the relatively flat and smooth surfaces of the initial strip into sharp and angular knurls. Visually, high roughness was added to the overall surface, but the knurl tops remained flat and smooth, this indicated low microtexture roughness. The second process step, grit blasting was used. An image of the resulting surface is illustrated in FIG. 11B. As shown in FIG. 11B, grit blasting added extensive microtexture roughness to the knurled tops, side faces, and valleys. The once sharp interfaces between the knurl sides and tops were interrupted and rounded, highly angular areas were rounded, and the overall flatness of the knurl features were visually reduced by about half.

In a third process step, extended etching was employed to further round the roughened and angular knurled surfaces, increase the surface microtexture area, and to visually reduce flat areas by 95 percent. An image of the resulting surface is illustrated in FIG. 11C. As a result of the processing, sharp and highly angular features were eliminated; flat areas were transformed into areas having high microtexture roughness, and high surface area features were formed. The resulting surfaces were clean and had high surface energy.

TABLE 1
Visual Descriptions of Example 1 Results

| | | Plateau Tops, Valleys |
|---|---|---|
| State of Coil | Plateau Edges | and Facets (sidewalls) |
| Strip | None | None |
| Knurled | Sharp & Angular | Flat and Smooth |
| Grit Blasted | Interrupted and | Flatness reduced micro- |
| | rounded | roughness introduced |
| Final Extended | No sharp or | High micro-roughness |
| Etch | angular features | and high surface area |

### Example 2: Quantitative Comparisons of Treated Surfaces

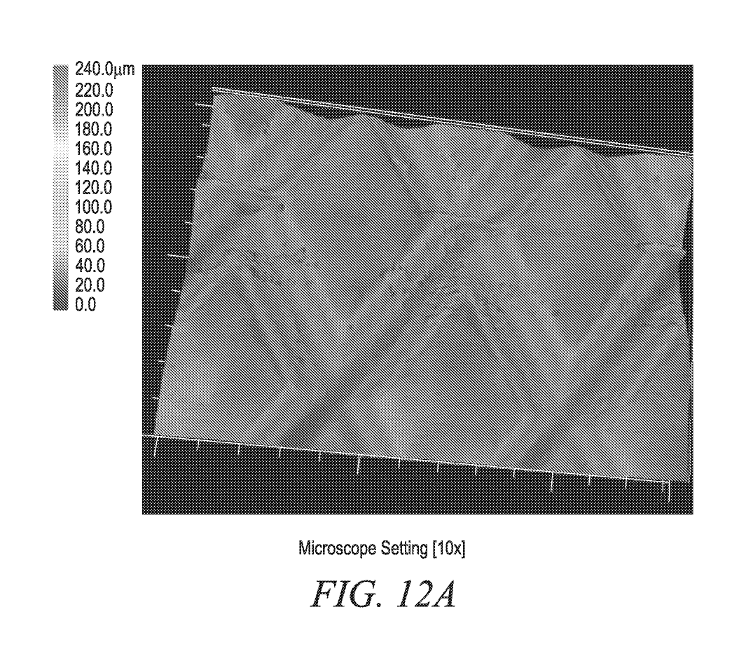

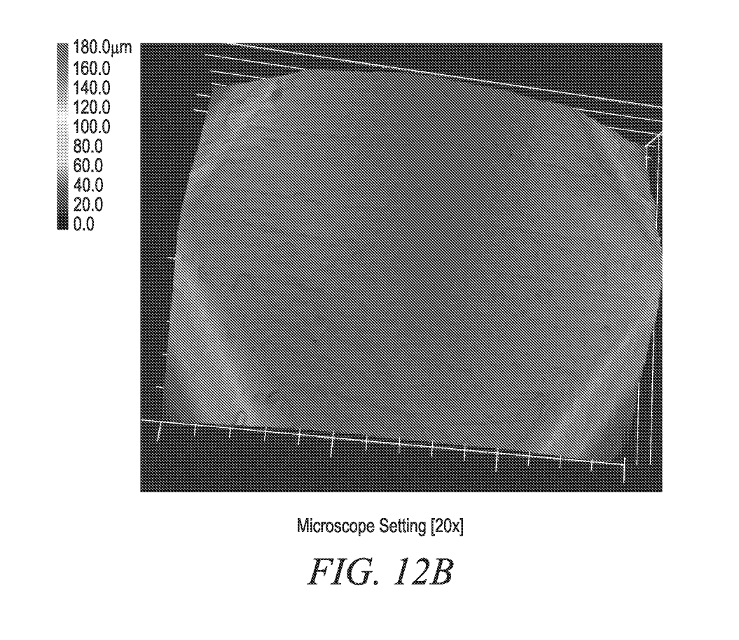

FIGS. 12A, 12B, 13A, 13B, 14A, and 14B were captured using a Keyence Color 3D Laser Confocal Microscope model VK9710 with the 10× and 20× settings. These captured images allow macrotexture analysis to be completed.

FIG. 12A is a comparative example of a knurled surface of a sputtering coil material at 10× magnification. As illustrated in the image, the knurled surface contains a uniform pattern containing plateaus and valleys. Each raised plateau is relatively flat and has a smooth planar surface. The data for the surface roughness and surface area are contained in Tables 2 and 3.

The macro surface roughness is the roughness of the overall surface of the sputtering coil. It thus includes the surface area over a plurality of plateaus and the valleys in between them. The percent increase of macrotexture surface area versus planar surface shows how the surface texturization techniques increase as compared to the area of a flat planar surface covering the same space. The knurl face (micro) surface roughness is the roughness measured over the area of a single knurling plateau. Thus, as expected, the roughness comparison for a surface that is only knurled is 100% since the area over just a single plateau is essentially smooth. The percent increase of microtexture surface area vs. planar surface shows how the actual surface area of just a knurled plateau increases when compared to the surface area of a planar surface, or simply a flat knurled plateau.

FIG. 12B is a comparative example of the knurled surface of a sputtering coil material, shown in FIG. 12A, only now at 20× magnification.

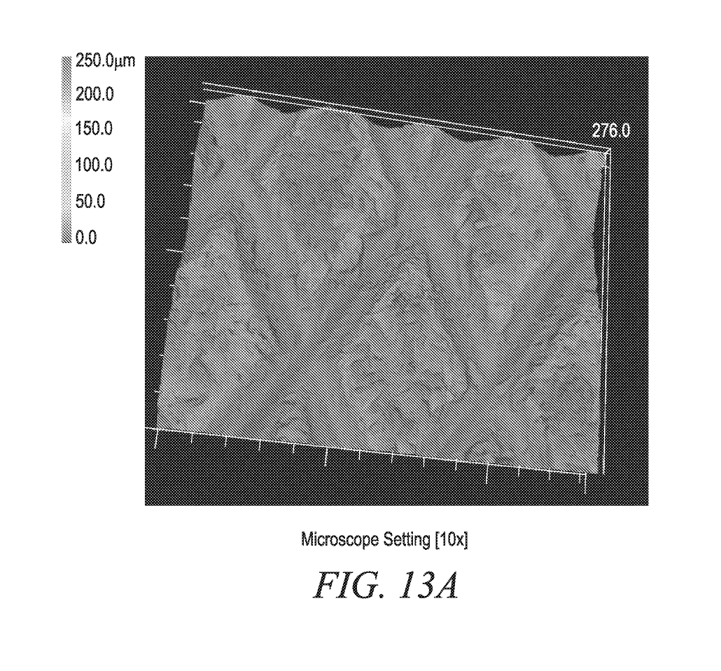

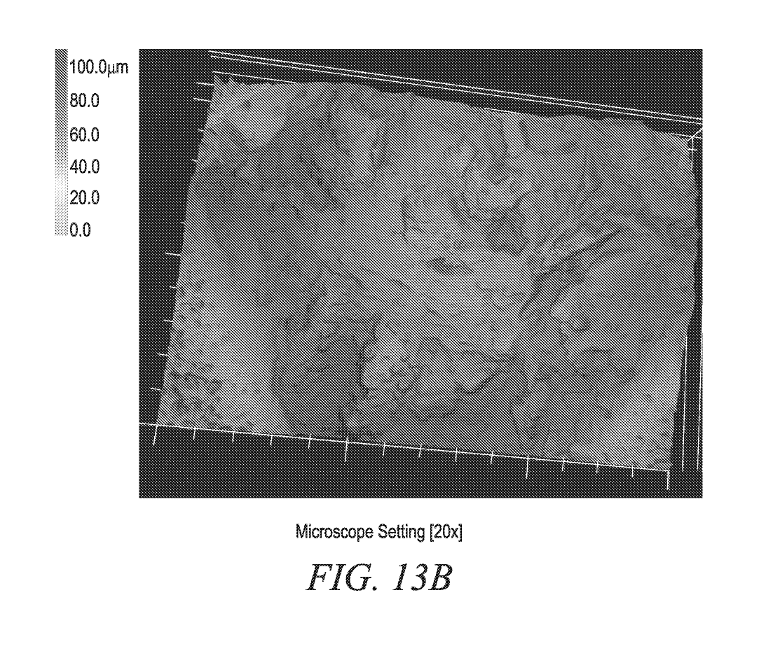

FIG. 13A is an inventive example of the knurled surface of FIGS. 12A and 12B after undergoing a grit blast step, shown at 10× magnification. Comparing the images in FIGS. 12A and 13A, the surface texture of each plateau and valley in FIG. 13A is noticeably rougher than in FIG. 12A. The area of each plateau and valley also has an increased surface area due to the roughness and texture added by the grit blasting step. The values for the roughness and surface area are contained in Tables 2 and 3. As the data in Tables 2 and 3 illustrate, the surface roughness and surface area increase considerably after a grit blasting step has been completed.

FIG. 13B is an inventive example of the knurled surface of FIGS. 12A and 12B after undergoing a grit blast step, shown at 20× magnification.

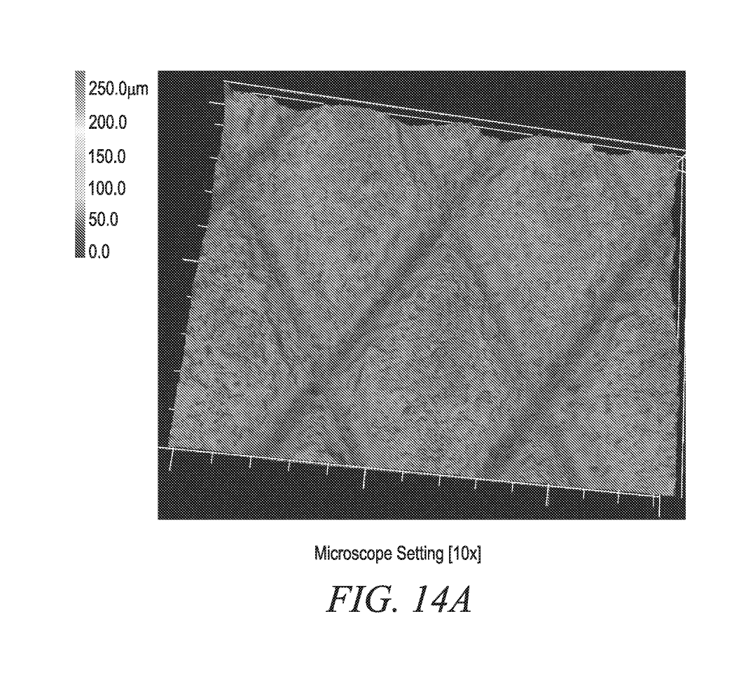

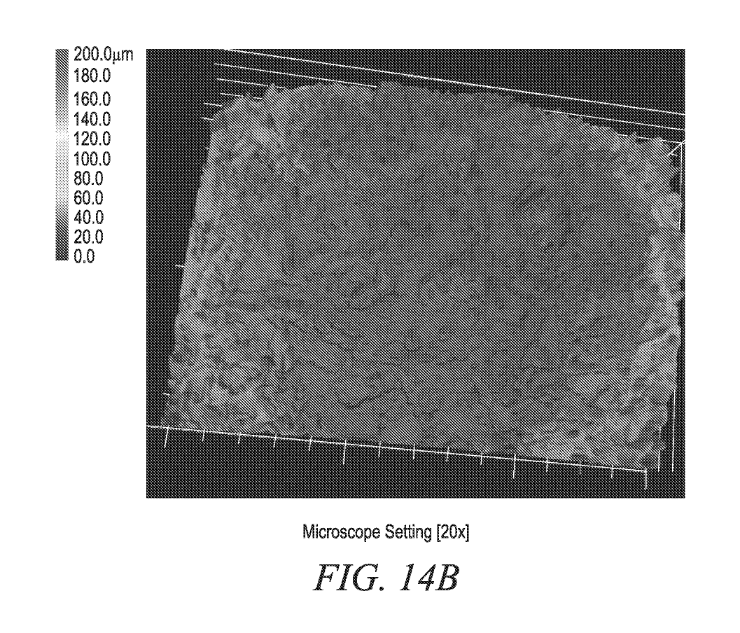

FIG. 14A is an inventive example of the knurled surface of FIGS. 12 and 13 after undergoing an etching step, shown at 10× magnification. Comparing the images in 12A, 13A, and 14A, the surface of each plateau and valley have progressively increased surface area with each step. The texture shown in FIG. 14A illustrates that the surface area of FIG. 13A can be increased still with an additional step after grit blasting; in this example the additional step used was etching. The etching step serves to increase the surface area, and provides for mechanical adhesion. Comparing the surface area on just the top of a single plateau, the surface area has increased to 180% as a result of grit blasting followed by etching. The overall surface area, taking into account the surface area of a plurality of knurling plateaus and the valleys in between them, has increased to 210%.

FIG. 14B is an inventive example of the knurled surface of FIGS. 12 and 13 after undergoing an etching step, shown at 20× magnification.

Samples were analyzed using a Keyence Color 3D Laser Confocal Microscope Model VK9710 with 10× and 20× magnification. Micrographs are displayed in FIGS. 12-14 and the associated data is contained in Tables 2 and 3. Using three process steps (knurling, grit blasting, and extended etching), the method developed macro and microtexture, that has beneficial features including equivalent macroroughness yet much improved microroughness and micro surface area with no sharp or highly angular features. The macrotexture breaks up large continuous areas to reduce delamination that would otherwise be caused by temperature variations during sputtering. The microtexture surface roughness is 480% of the base knurled surface. Surface area was drastically improved compared to a flat surface.

TABLE 2
Surface Roughness Data of Example 2

| | Before | After | After Grit | |
|---|---|---|---|---|
| | Knurl | Knurl | Blast | Final |
| Macro Surface Roughness | 0.4 | 58 | 64 | 52 |
| (Ra value (μm)) | | | | |
| Knurl Face (Micro) Surface | 0.4 | 1.5 | 7 | 7.2 |
| Roughness (Ra value (μm)) | | | | |
| Comparison of Microtexture | N/A | Base | 467% | 480% |
| Surface Roughness | | | | |

TABLE 3
Surface Area Data of Example 2.

| (Micron squared/ | Before | After | After Grit | |
|---|---|---|---|---|
| micron squared) | Knurl | Knurl | Blast | Final |
| Percent of Macrotexture | 100% | 125% | 163% | 210% |
| Surface Area vs. Planar | | | | |
| surface | | | | |
| Percent of Microtexture | 100% | 110% | 140% | 180% |
| Surface Area vs. Planar | | | | |
| surface | | | | |

The instant disclosure achieves improved device yield using an improved surface texture. Product defectivity is reduced by increasing microroughness and simultaneously increasing surface area and surface activity, rather than by increasing macroroughness. This development reduces arcing and particulate during sputtering resulting in improved product yield.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

1-10. (canceled)

11. A high surface area coil for use with a physical vapor deposition apparatus, the high surface area coil comprising:
a first surface;
at least a portion of the first surface having a patterned macrotexture with a surface roughness (Ra) between about 15 μm and about 150 μm; and
at least a portion of the first surface having the patterned macrotexture has a microtexture with a surface roughness (Ra) between about 3 μm and 15 μm.

12. The high surface area coil of claim 11, wherein the patterned macrotexture surface roughness (Ra) is between about 35 μm and about 75 μm.

13. The high surface area coil of claim 11, wherein the microtexture surface roughness (Ra) is between about 5 μm and about 10 μm.

14. The high surface area coil of claim 11, wherein the portion of the first surface having the microtexture has a macrotexture percent surface area between about 140 percent to about 1000 percent.

15. The high surface area coil of claim 11, wherein the portion of the first surface having the microtexture has a macrotexture percent surface area between about 150 percent to about 400 percent.

16. The high surface area coil of claim 11, wherein the portion of the first surface having the patterned macrotexture has a microtexture percent surface area between about 140 percent to about 300 percent.

17. The high surface area coil of claim 11, wherein the microtexture is any one of a bead blasted, etched, e-beamed, shot-peened, grit blasted, machined, lasered, stamped, or microknurled texture.

18. The high surface area coil of claim 11, wherein the first surface has a roughened, textured surface as compared to a surface having a patterned macrotexture only.

19. A sputtering coil for use with a physical vapor deposition apparatus, the sputtering coil comprising:
a first surface, wherein at least a portion of the first surface has a percent surface area between about 120 percent and about 1000 percent.

20. The sputtering coil of claim 19, wherein the first surface has a percent surface area between about 150 percent and about 300 percent.

21. The sputtering coil of claim 19, wherein the first surface has a percent surface area between about 180 percent and about 250 percent.

22. The sputtering coil of claim 19, wherein the first surface has a patterned macrotexture with a surface roughness (Ra) between about 35 μm and about 75 μm.

23. The sputtering coil of claim 22, wherein the patterned macrotexture is any one of a knurled or over knurled pattern.

24. The sputtering coil of claim 19, wherein the first surface has a microtexture with a surface roughness (Ra) between about 3 μm and 10 μm.

25. The sputtering coil of claim 24, wherein the microtexture is a bead blasted, etched, e-beamed, shot-peened, grit blasted, machined, lasered, stamped, or microknurled texture.

26. A method of forming a high surface area coil for use with a physical vapor deposition apparatus, method comprising:
forming a patterned macrotexture on at least a portion of a first surface of a coil; and
forming a microtexture on at least a portion of the first surface containing the patterned macrotexture,
wherein after forming the patterned macrotexture and forming the microtexture the coil has a percent surface area of at least 120 percent.

27. The method of claim 26, wherein forming the patterned macrotexture comprises at least one of forming a knurled, machined, or embossed pattern.

28. The method of claim 26, wherein forming the microtexture comprises at least one of grit blasting, etching, e-beaming, shot-peening, machining, lasering, stamping, or knurling.

29. The method of claim 26, wherein after forming the patterned macrotexture and forming the microtexture the coil has a surface roughness (Ra) of between about 2 μm and about 75 μm.

30. The method of claim 26, wherein the percent surface area of the coil is between about 120 percent and 1000 percent.
